(19) United States
(12) Patent Application Publication
(10) Pub. No.: US 2026/0317937 A1
(43) Pub. Date: Oct. 15, 2026

(54) PLATING SOLUTION COMPOSITION, PLATING METHOD USING THE SAME, AND PLATED FILM FORMED THEREBY

(71) Applicant: DONGWOO FINE-CHEM CO., LTD., Iksan-si (KR)

(72) Inventors: Dong-Ryul LEE, Iksan-si (KR); O-Byoung KWON, Iksan-si (KR); Ji-Eun HEO, Iksan-si (KR)

(73) Assignee: DONGWOO FINE-CHEM CO., LTD., Iksan-si (KR)

(21) Appl. No.: 19/641,603

(22) Filed: Apr. 8, 2026

(30) Foreign Application Priority Data
Apr. 10, 2025 (KR) 10-2025-0046863

(51) Int. Cl. C25D 3/46; C25D 3/30; C25D 7/12; H10W 72/00; H10W 72/30

(52) U.S. Cl. CPC C25D 3/46; C25D 3/30; C25D 7/12; H10W 72/01335; H10W 72/3524

(57) ABSTRACT

The present disclosure relates to a plating solution composition, a plating method using the same, and a plating film formed thereby, and provides a tin-silver plating solution composition which is capable of forming uniform and fine grains by having a nucleation index (Y) optimized depending on the specific content ranges of a tin ion source and a grain refiner and a specific voltage range.

### CROSS-REFERENCE TO RELATED APPLICATION(S)

This application claims the benefit under 35 USC 119(a) of Korean Patent Application No. 10-2025-0046863, filed on Apr. 10, 2025 with the Korean Intellectual Property Office, the disclosure of which is incorporated herein by reference in its entirety.

### BACKGROUND

### 1. Technical Field

The present disclosure relates to a plating solution composition, a plating method using the same, and a plated film formed thereby.

### 2. Related Art

With the trend of miniaturization of electronic components such as semiconductor devices and PCBs, there is a need for technology capable of realizing high density and high integration. In particular, maintaining fine uniformity of a plated film and stability during high-speed plating has emerged as an important technical challenge for realizing high density and high integration of semiconductor devices.

Since the beginning of the electronics industry, the soldering process has been established as the most fundamental joining technology in the assembly of all electronic products, and the application of soldering has increased even more with the emergence of packaging technology. Soldering is a method of joining base materials (materials to be joined) by allowing molten solder with a melting point lower than 450° C. to penetrate and spread into the gaps between the base materials. Soldering is a type of joining technology, but it is distinguished from similar fusion welding in that the base materials are not melted during the process, but only the solder is melted to form a joint, and a metallic chemical bond is formed between the soldered base material and the solder. During soldering, the molten solder penetrates into the gap between the metal pad or via hole of a substrate and the lead or metal electrode of an electronic component to form a joint while forming an intermetallic compound (IMC) at the interface of the joint. Since the intermetallic compound has a significant effect on the mechanical strength and lifespan of the soldering part, it is desirable to inhibit the formation of the intermetallic compound (IMC) at the joint during the soldering process.

However, conventional tin-silver plating compositions have problems in that the formation of intermetallic compounds (IMCs) and voids during the reflow process increases and the grains become excessively large, which reduces the reliability of the joint.

In this regard, Korean Patent Application Publication No. 10-2010-0038576 describes a plating composition that improves flatness, etc. by using a disulfide compound as an accelerator. However, the technology disclosed therein has problems in that the formation of intermetallic compounds (IMCs) and voids is not inhibited, and nucleation tendency is not good, so that the grains become excessively large, resulting in a poor surface profile of the plated film.

Accordingly, there is a need to develop a plating solution composition that inhibits the formation of intermetallic compounds (IMCs) and voids, has an excellent nucleation tendency, and forms fine grains, thereby providing a plated film with an excellent surface profile.

### PRIOR ART DOCUMENTS

### Patent Documents

(Patent Document 1) Korean Patent Application Publication No. 10-2010-0038576

### SUMMARY

The present disclosure has been made in order to solve the above-described problems occurring in the prior art, and an object of the present disclosure is provide a tin-silver plating solution composition which is capable of forming uniform and fine grains by having a nucleation index (Y) optimized depending on the specific content ranges of a tin ion source and a grain refiner and a specific voltage range. Thereby, it is possible to improve the structural stability of a plated film and maintain excellent reliability even during a reflow process.

However, the problems to be solved by the present disclosure are not limited to the problem mentioned above, and other problems not mentioned will be clearly understood by those skilled in the art from the following description.

To achieve the above object, the present disclosure provides a plating solution composition for use in an electrochemical plating process, the plating solution composition including a tin ion source, a silver ion source, an organic acid, a complexing agent, a leveling agent, and a grain refiner, and having a Y value of 1 to 5,000 as calculated by Equation 1 below:

Y=−25(x+400)(x+800)δε [Equation 1]
wherein x represents a voltage (mV) applied during the plating process, δ represents the concentration (kg/L) of the tin ion source, ε represents the concentration (kg/L) of the grain refiner, Y represents the nucleation index, and x is −400 mV to −800 mV.

In the present disclosure, in Equation 1 above, the concentration F of the grain refiner may be 0.1 g/L to 10 g/L.

In the present disclosure, in Equation 1 above, the concentration F of the grain refiner may be 1.5 g/L to 9 g/L.

In the present disclosure, the grain refiner may include at least one selected from among dodecyl trimethylammonium bromide, ditallow dimethylammonium chloride, stearyl trimethylammonium chloride, trihexadecylmethylammonium chloride, and tallow methyl ethoxylated ammonium chloride.

In the present disclosure, the tin ion source may include at least one selected from among tin sulfate, tin hydrochloride, tin sulfamate, tin acetate, tin phosphate, tin methanesulfonate, tin gluconate, and tin carboxylate.

In the present disclosure, the silver ion source may include at least one selected from among silver sulfate, silver chloride, silver sulfamate, silver acetate, silver phosphate, silver methanesulfonate, silver gluconate, and silver carboxylate.

The present disclosure also provides a plating method including steps of: providing the plating solution composition; and immersing a semiconductor wafer in the plating solution composition.

The present disclosure also provides a plated film formed using the plating solution composition.

The present disclosure provides a plating method using the plating solution composition and a substrate formed thereby.

The plating solution composition according to the present disclosure may form a plated film having uniform and fine grains by having a nucleation index (Y) controlled within a specific range depending on the specific content ranges of the tin ion source and the grain refiner and a specific voltage range, thereby increasing the reliability of the plating process. In addition, the plating solution composition according to the present disclosure has the technical advantage of being able to improve the reliability of a joint by effectively inhibiting the formation of intermetallic compounds (IMCs) and enable stable plating even over a wide voltage range.

### BRIEF DESCRIPTION OF THE DRAWINGS

FIGS. 1 to 4 are scanning electron microscope images showing the profiles of plated films formed using plating solution compositions according to Example 2 of the present disclosure and Comparative Examples 1, 3 and 4, respectively.

### DETAILED DESCRIPTION

The present disclosure relates to a plating solution composition, a plating method using the same, and a plated film formed thereby, and is characterized by forming a plated film having uniform and fine grains by controlling the nucleation index (Y) within a specific range depending on the specific content ranges of a tin ion source and a grain refiner and a specific voltage range, thereby increasing the reliability of the plating process.

In the present disclosure, “plating” and “deposition” may be used substantially interchangeably and are not limited to a specific form.

In the present disclosure, “plating” may be for manufacturing any substrate, interconnect, and/or electrode, etc. which are/is used in the manufacture of electronic products, and in particular, may be for substrates, interconnects, and electrodes, which are used in the manufacture of semiconductor devices or PCBs, without being limited thereto. The present disclosure may relate to a plating solution which is used for a lead frame or a ball grid array (BGA) for substrate connection in a semiconductor packaging process.

In the present specification, when any part is referred to as “including” any component, this means that the part does not exclude other components, but may include other components, unless otherwise specifically stated.

In the present disclosure, the thickness of the plated film is not particularly limited, but may be 0.1 to 500 μm.

The plating in the present disclosure may be electroplating and may be performed by applying a voltage of 400 mV to 800 mV. According to the present disclosure, when the plating process is performed by applying a voltage within the above range, the nucleation index Y of Equation 1 above may be controlled within a range of 1 to 5,000, and accordingly, a plated film with excellent nucleation tendency may be provided.

### <Plating Solution Composition>

The plating solution composition of the present disclosure is a plating solution composition for use in an electrochemical plating process, and is characterized by including a tin ion source, a silver ion source, an organic acid, a complexing agent, a leveling agent, and a grain refiner, and having a Y value of 1 to 5,000 as calculated by Equation 1 below:

Y=−25(x+400)(x+800)δε [Equation 1]
wherein x represents a voltage (mV) applied during the plating process, δ represents the concentration (kg/L) of the tin ion source, ε represents the concentration (kg/L) of the grain refiner, Y represents the nucleation index, and x is −400 mV to −800 mV.

In addition, the plating solution composition may further include known additives within a range that does not impair the object of the present disclosure.

### (A) Tin Ion Source

The tin ion source (A) included in the plating solution composition of the present disclosure is a material that supplies tin ions during tin-silver plating.

The tin ion source may be a water-soluble tin compound. The tin ion source may be, for example, at least one selected from the group consisting of tin sulfate, tin hydrochloride, tin sulfamate, tin acetate, tin phosphate, tin methanesulfonate, tin gluconate, and tin carboxylate, and preferably may be tin methanesulfonate having high solubility.

The content of the tin ion source may be 1 g/L to 500 g/L, preferably 10 g/L to 300 g/L. If the content of the tin ion source is less than 1 g/L, tin precipitation may be insufficient, so that the silver content may increase or foreign substances may be included, and thus adhesion to a substrate may be reduced. If the content of the tin ion source is more than 500 g/L, a problem may arise in that the plated surface becomes uneven due to precipitation. In particular, the content of the tin ion source in the present disclosure is directly related to the nucleation index Y calculated by Equation 1 above, and as the content of the tin ion source increases, the nucleation tendency becomes better. When the content of the tin ion source satisfies the range of 10 g/L to 300 g/L, it is easy to control the nucleation index Y calculated by Equation 1 above within the range of 1 to 5,000.

### (B) Silver Ion Source

The silver ion source (B) included in the plating solution composition of the present disclosure is a material that supplies silver ions during tin-silver plating. It may be incorporated into tin during plating, thereby lowering the reflow process temperature of the plated film.

The silver ion source may be a water-soluble silver compound. The silver ion source may be, for example, at least one selected from the group consisting of silver sulfate, silver hydrochloride, silver sulfamate, silver acetate, silver phosphate, silver methanesulfonate, silver gluconate, and silver carboxylate, and preferably may include silver methanesulfonate.

The content of the silver ion source may be 0.01 g/L to 10 g/L, preferably 0.1 g/L to 5 g/L. If the content of the silver ion source is less than 0.01 g/L, the silver content in the plated film may be insufficient, and thus the reflow process temperature may not decrease, and if the content of the silver ion source is more than 5 g/L, the reflow process temperature may increase due to the precipitation of silver in the solution and the high silver content in the plated film.

### (C) Organic Acid

The organic acid (C) included in the plating solution composition of the present disclosure serves to impart electrical conductivity to the plating solution composition. The organic acid may dissolve in the solution and accelerate the electrolysis of the tin-silver plating composition.

The organic acid may be at least one selected from the group consisting of acetic acid, methanesulfonic acid, ethanesulfonic acid, citric acid, and formic acid, and preferably may include methanesulfonic acid.

The content of the above organic acid may be 10 g/L to 400 g/L, preferably 100 g/L to 300 g/L. If the content of the organic acid is less than 10 g/L, the efficiency may be reduced due to low electrical conductivity, and conversely, if the content of the organic acid is more than 400 g/L, problems with plating quality may occur due to excessive reaction.

### (D) Complexing Agent

The complexing agent (D) included in the plating solution composition of the present disclosure serves to inhibit the reduction and precipitation of silver ions.

The complexing agent is not particularly limited, but may include, as a functional group, ether, amine, or sulfide. The complexing agent may be, for example, at least one selected from the group consisting of ethylenediaminetetraacetic acid, [bis(phosphonomethyl)amino]methylphosphonic acid, trans-1,2-diaminocyclohexane-N,N,N′,N′-tetraacetic acid, and sodium citrate.

The content of the complexing agent may be 0.1 g/L to 50 g/L, preferably 1 g/L to 20 g/L. If the content of the complexing agent is less than 1 g/L, silver ions precipitate, and thus the stability of the tin plating solution may not be ensured, and conversely, if the content of the complexing agent is more than 50 g/L, there is a problem in that the complexing agent does not dissolve.

### (E) Leveling Agent

The leveling agent (E) included in the plating solution composition of the present disclosure serves to improve the wettability of the tin-silver plating solution.

The leveling agent may include at least one selected from the group consisting of nonionic surfactants, cationic surfactants, anionic surfactants, and synthetic polymers. The leveling agent may be, for example, any one or more selected from among 2-naphthyl ethyl ether, polyoxyalkylene ether, polyoxyethylene glycol, polyoxyethylene alkylphenyl ether, and polyoxyethylene alkyl amine ether.

The content of the leveling agent may be 1 g/L to 100 g/L, preferably 10 g/L to 50 g/L.

### (F) Grain Refiner

The grain refiner (F) included in the plating solution composition of the present disclosure serves to inhibit grain growth during tin-silver plating, thereby aiding nucleation.

The grain refiner may include, as a functional group, ammonium, amine, or amide. The grain refiner may include, for example, any one or more selected from the group consisting of dodecyl trimethylammonium bromide, ditallow dimethylammonium chloride, stearyl trimethylammonium chloride, trihexadecylmethylammonium chloride, tallow alkyl methyl ethoxylated ammonium chloride, and bis(2-hydroxyethyl)methyl(tridecyl)azanium.

The content of the grain refiner may be 0.1 g/L to 10 g/L, preferably 0.5 g/L to 5 g/L. If the content of the grain refiner is 0.1 g/L or less, there is a problem in that the grains become larger, and if the content of the grain refiner is more than 5 g/L, there is a problem in that plating does not occur due to excessive growth inhibition. The present disclosure is technically characterized by controlling the content of the grain refine included in the plating solution composition to 0.1 g/L to 10 g/L, thereby controlling the nucleation index Y calculated by Equation 1 within a range of 1 to 5,000. Accordingly, when a plating process is performed out using the plating solution composition of the present disclosure, there is a technical advantage in that a plated film with an excellent nucleation tendency and an excellent surface profile may be provided.

### (G) Water

The water included in the plating solution composition of the present disclosure may be deionized water for semiconductor processes. Preferably, the deionized water used may have a resistivity of 18 MΩ/cm or higher. In addition, the water may be included as a remainder. Here, the remainder means an amount such that the total weight of the composition including the essential components and other components included in the plating solution composition of the present disclosure becomes 100 wt %.

### Nucleation Index Y

The plating solution composition of the present disclosure is characterized by having a Y value of 1 to 5,000 as calculated by Equation 1 below. As the plating solution composition of the present disclosure has a nucleation index (Y) calculated by Equation 1 below, controlled within a certain range, it may form a plated film having uniform and fine grains, thereby increasing the reliability of the plating process.

Y=−25(x+400)(x+800)δε [Equation 1]
wherein x represents a voltage (mV) applied during the plating process, δ represents the concentration (kg/L) of the tin ion source, ε represents the concentration (kg/L) of the grain refiner, Y represents the nucleation index, and x is −400 mV to −800 mV.

The nucleation index (Y) calculated by Equation 1 above may be used as an indicator of the tendency for nuclei to form on the surface of the plated film during the plating process. As the value of the nucleation index Y is larger, the rate of nucleation is higher than the rate at which nuclei formed on the surface of the plated film grow, and accordingly, there is a tendency to form a plated film with uniform and fine grains. Conversely, as the value of the nucleation index Y is smaller, the rate of nucleus growth is higher than the rate at which nuclei are formed on the surface of the plated film, and accordingly, the grain size tends to become larger, forming a plated film with a non-uniform profile. As uniform and fine grains are formed on the surface of the plated film, there is an advantage in that the surface gloss and flatness of the plated film are improved.

The value of the nucleation index Y calculated by Equation 1 above is influenced by the voltage (mV) applied during the plating process, the concentration (kg/L) of the tin ion source, and the concentration (kg/L) of the grain refiner, and may have both positive and negative values according to Equation 1 above. The present disclosure is intended to provide a plating solution composition that forms a plated film with an excellent profile during the plating process by controlling the value of the nucleation index Y calculated by Equation 1 above within 1 to 5,000. Preferably, the value of the nucleation index Y calculated by Equation 1 above may be 50 to 4,500, more preferably 200 to 4,500. When the value of the nucleation index Y calculated by Equation 1 above satisfies the above range, the number of nuclei formed per unit area of the plated film surface (EA/μm²) exceeds 1, so that more than 1 grain may be formed per μm². As the number of grains formed per unit area increases, the rate of nucleation is higher than the rate of nucleus growth, and thus finer grains may be formed, thereby forming a plated film with a uniform profile, and thus the reliability of the plating process may be increased. If the value of the nucleation index Y calculated by Equation 1 above is less than 1, there is a problem in that one grain is formed per few μm² to several thousand μm², and thus the size of the grain becomes excessively large, and accordingly, the profile of the plated film becomes non-uniform. If the value of the nucleation index Y calculated by Equation 1 above is more than 5,000, there is a problem in that plating is excessively inhibited, and thus the profile of the plated film becomes non-uniform.

### <Plating Method Using Plating Solution Composition and Plated Film Formed Thereby>

The present disclosure includes a plating method using the plating solution composition described above, and includes any plated film manufactured or formed using the plating solution composition or the plating method.

The above-described characteristics of the plating solution composition may be applied without limitation to the plating method and plated film of the present disclosure.

Specifically, the plating method of the present disclosure may include:
step a) of providing the plating solution composition of the present disclosure; and
step b) of immersing a semiconductor wafer in the plating solution composition.

In the present disclosure, the semiconductor wafer may be at least one of a silicon wafer substrate and a PCB substrate, without being limited thereto.

Hereinafter, the present disclosure will be explained in more detail through examples. However, the following examples are intended to explain the present disclosure in more detail, and the scope of the present disclosure is not limited by the following examples.

### Examples 1 to 6 and Comparative Examples 1 to 4: Preparation of Plating Solution Compositions

Plating solution compositions were prepared according to the components and contents shown in Table 1 below, with the remainder being deionized water. In addition, the nucleation index when the voltage shown in Table 1 below was applied was calculated according to Equation 1 below, and the results are shown in Table 1 below.

Y=−25(x+400)(x+800)δε [Equation 1]

In Equation 1 above, x is the applied voltage (mV) shown in Table 1 below, δ is the concentration (g/L) of the tin ion source shown in Table 1 below converted into units of kg/L, and ε is the concentration (g/L) of the grain refiner shown in Table 1 below converted into units of kg/L.

TABLE 1

| | (A) | (B) | (C) | (D) | (E) | (F) | Applied | |
|---|---|---|---|---|---|---|---|---|
| Composition | Tin ion | Silver ion | Organic | Complexing | Leveling | Grain | voltage | Nucleation |
| (unit: g/L) | source | source | acid | agent | agent | refiner | (mV) | index Y |
| Example 1 | 60 | 0.5 | 100 | 5 | 30 | 1.5 | −600 | 90 |
| Example 2 | 300 | 0.5 | 100 | 5 | 30 | 9 | −600 | 2700 |
| Example 3 | 60 | 0.5 | 100 | 5 | 30 | 4 | −600 | 240 |
| Example 4 | 60 | 0.5 | 100 | 5 | 30 | 1 | −700 | 45 |
| Example 5 | 60 | 0.5 | 100 | 5 | 30 | 1 | −790 | 5.85 |
| Example 6 | 50 | 0.5 | 100 | 5 | 30 | 0.3 | −410 | 1.46 |
| Comparative | 60 | 0.5 | 100 | 5 | 30 | 0.01 | −600 | 0.6 |
| Example 1 | | | | | | | | |
| Comparative | 60 | 0.5 | 100 | 5 | 30 | 1.5 | −900 | −112.5 |
| Example 2 | | | | | | | | |
| Comparative | 60 | 0.5 | 100 | 5 | 30 | 1.5 | −100 | −472.5 |
| Example 3 | | | | | | | | |
| Comparative | 1 | 0.5 | 100 | 5 | 30 | 1 | −500 | 0.75 |
| Example 4 | | | | | | | | |

(A) Tin ion (Sn²⁺) source: Electrolysis of tin in the form of ionic salt in methanesulfonic acid solution
(B) Silver ion (Ag⁺) source: Silver methanesulfonate (Ag-MSA)
(C) Organic acid: Methanesulfonic acid
(D) Complexing agent: 3,6-Dithia-1,8-octanediol
(E) Leveling agent: Ethoxylated beta-naphthol
(F) Grain refiner: Octadecyl trimethylammonium chloride

### Experimental Example 1: Evaluation of Nucleation Tendency

Using each of the plating solution compositions of Examples 1 to 6 and Comparative Examples 1 to 4, plating was performed to a thickness of 0.2 m on a patterned wafer (semiconductor silicon wafer). Copper electroplating was performed by applying current, and the voltage shown in Table 1 above was applied.

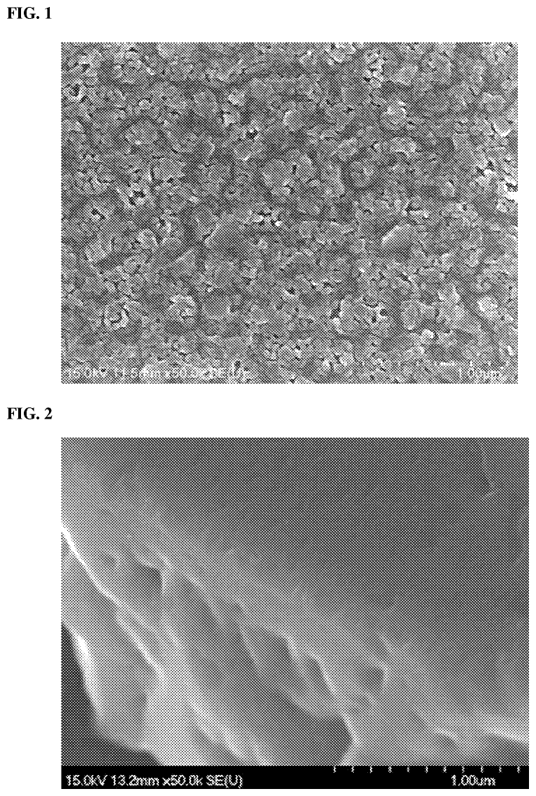

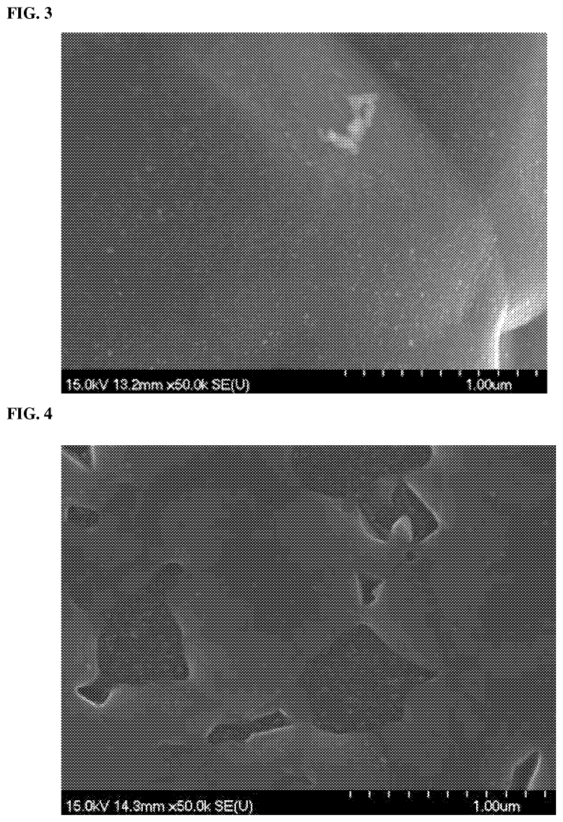

For the plating results, the profiles of the plated films were scanned using a scanning electron microscope (SEM, S-4700 Hitachi), the number of nuclei formed per unit area (EA/μm²) was measured, and the results are shown in Table 2 below. Based on the number of nuclei formed per unit area, the nucleation tendency was evaluated according to the following classification criteria, and the evaluation results are shown in Table 2 below. Among the plating results, the profiles of the plated films formed by performing the plating process using the plating solution compositions of Example 2 and Comparative Examples 1, 3 and 4 are shown in FIGS. 1 to 4.

### Evaluation Criteria for Nucleation Tendency

⊚: the number of nuclei formed per unit area (EA/μm²) is 40 or more
∘: the number of nuclei formed per unit area (EA/μm²) is 1 or more and less than
X: the number of nuclei formed per unit area (EA/μm²) is less than 1

### Experimental Example 2: Evaluation of IMC Inhibitory Effect

For the plating results, the profiles of the plated films were scanned using a scanning electron microscope (SEM, S-4700 Hitachi), the effect of inhibiting IMC was evaluated according to the thickness (μm) of the intermetallic compound (IMC) layer, and the evaluation results are shown in Table 2 below.

### Evaluation Criteria for IMC Inhibitory Effect

⊚: the IMC layer thickness is less than 1 μm
∘: the IMC layer thickness is 1 μm or more and less than 3 μm
X: the IMC layer thickness is 3 μm or more

TABLE 2

| | | Number of nuclei formed | Nucleation | IMC inhibitory |
|---|---|---|---|---|
| | Nucleation index Y | per unit area (EA/μm²) | tendency | effect |
| Example 1 | 90 | 43.90 | ⊚ | ◯ |
| Example 2 | 2700 | 95.03 | ⊚ | ⊚ |
| Example 3 | 240 | 79.88 | ⊚ | ⊚ |
| Example 4 | 45 | 23.09 | ◯ | ⊚ |
| Example 5 | 5.85 | 16.64 | ◯ | ◯ |
| Example 6 | 1.46 | 14.64 | ◯ | ◯ |
| Comparative | 0.6 | 0.0011 | X | X |
| Example 1 | | | | |
| Comparative | −112.5 | 0.0009 | X | X |
| Example 2 | | | | |
| Comparative | −472.5 | 0.0002 | X | X |
| Example 3 | | | | |
| Comparative | 0.75 | 24.02 | ◯ | X |
| Example 4 | | | | |

Referring to the results in Table 2 above and FIG. 1, it could be confirmed that, in the case of the plated films formed by performing the plating process using the plating solution composition of Examples 1 to 6 of the present disclosure, in which the Y value calculated by Equation 1 satisfied 1 to 5,000, the number of nuclei formed per unit area was more than 1 EA/μm², indicating that fine grains were formed. On the other hand, it could be confirmed that, in the case of the plated films formed by performing the plating process using the plating solution compositions of Comparative Examples 1 to 4, one grain was formed per few μm² to several thousand μm², indicating that the size of the grains became excessively large, and thus the profiles of the plated films were non-uniform (see Table 1 above and FIGS. 2, 3 and 4). In addition, in the case of the plated films formed by performing the plating process using the plating solution composition of Examples 1 to 6 of the present disclosure, in which the Y value calculated by Equation 1 satisfied 1 to 5,000, the effect of inhibiting IMC formation was excellent, and thus the durability of the soldering part was excellent. On the other hand, in the case of the plated films formed by performing the plating process using the plating solution compositions of Comparative Examples 1 to 4 in which the Y value was outside the range of 1 to 5,000, there was a problem in that an IMC was formed along the interface of the joint, and a vacancy was formed inside the plated film due to hydrogen generation, which resulted in a decrease in the reliability of the plating process.

What is claimed is:

1. A plating solution composition for use in an electrochemical plating process, the plating solution composition comprising a tin ion source, a silver ion source, an organic acid, a complexing agent, a leveling agent, and a grain refiner, and having a Y value of 1 to 5,000 as calculated by Equation 1 below:
Y=−25(x+400)(x+800)δε [Equation 1]
wherein x represents a voltage (mV) applied during the plating process, δ represents a concentration (kg/L) of the tin ion source, ε represents a concentration (kg/L) of the grain refiner, Y represents a nucleation index, and x is −400 mV to −800 mV.

2. The plating solution composition of claim 1, wherein the concentration F of the grain refiner in Equation 1 above is 0.1 g/L to 10 g/L.

3. The plating solution composition of claim 2, wherein the concentration F of the grain refiner in Equation 1 above is 1.5 g/L to 9 g/L.

4. The plating solution composition of claim 1, wherein the grain refiner comprises at least one selected from among dodecyl trimethylammonium bromide, ditallow dimethylammonium chloride, stearyl trimethylammonium chloride, trihexadecylmethylammonium chloride, and tallow methyl ethoxylated ammonium chloride.

5. The plating solution composition of claim 1, wherein the tin ion source comprises at least one selected from among tin sulfate, tin hydrochloride, tin sulfamate, tin acetate, tin phosphate, tin methanesulfonate, tin gluconate, and tin carboxylate.

6. The plating solution composition of claim 1, wherein the silver ion source comprises at least one selected from among silver sulfate, silver chloride, silver sulfamate, silver acetate, silver phosphate, silver methanesulfonate, silver gluconate, and silver carboxylate.

7. A plating method comprising steps of:
providing a plating solution composition for use in an electrochemical plating process, the plating solution composition comprising a tin ion source, a silver ion source, an organic acid, a complexing agent, a leveling agent, and a grain refiner, and having a Y value of 1 to 5,000 as calculated by Equation 1 below; and
immersing a semiconductor wafer in the plating solution composition:
Y=−25(x+400)(x+800)δε [Equation 1]
wherein x represents a voltage (mV) applied during the plating process, δ represents a concentration (kg/L) of the tin ion source, ε represents a concentration (kg/L) of the grain refiner, Y represents a nucleation index, and x is −400 mV to −800 mV.

8. The plating method of claim 7, wherein the concentration F of the grain refiner in Equation 1 above is 0.1 g/L to 10 g/L.

9. The plating method of claim 8, wherein the concentration F of the grain refiner in Equation 1 above is 1.5 g/L to 9 g/L.

10. The plating method of claim 7, wherein the grain refiner comprises at least one selected from among dodecyl trimethylammonium bromide, ditallow dimethylammonium chloride, stearyl trimethylammonium chloride, trihexadecylmethylammonium chloride, and tallow methyl ethoxylated ammonium chloride.

11. The plating method of claim 7, wherein the tin ion source comprises at least one selected from among tin sulfate, tin hydrochloride, tin sulfamate, tin acetate, tin phosphate, tin methanesulfonate, tin gluconate, and tin carboxylate.

12. The plating method of claim 7, wherein the silver ion source comprises at least one selected from among silver sulfate, silver chloride, silver sulfamate, silver acetate, silver phosphate, silver methanesulfonate, silver gluconate, and silver carboxylate.

13. A plated film formed using the plating solution composition of claim 1.
